(19) United States
(12) Patent Application Publication
(10) Pub. No.: US 2006/0043384 A1
(43) Pub. Date: Mar. 2, 2006

(54) Vertical nitride semiconductor light emitting diode

(75) Inventors: Hyo Kyoung Cho, Suwon (KR); Min Ju Kim, Kimhae (KR); Kun Yoo Ko, Suwon (KR); Young Ho Park, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Suwon (KR)

(21) Appl. No.: 10/995,898

(22) Filed: Nov. 24, 2004

(30) Foreign Application Priority Data
Aug. 24, 2004 (KR) 2004-66619

(51) Int. Cl. H01L 33/00

(52) U.S. Cl. 257/79

(57) ABSTRACT

The present invention relates to a vertical nitride semiconductor light emitting diode. The present invention provides a vertical nitride semiconductor light emitting diode comprising a first conductive nitride semiconductor layer including an upper surface having a first electrode formed thereon; an active layer formed on a lower surface of the first conductive nitride semiconductor layer; a second conductive nitride semiconductor layer formed on a lower surface of the active layer; a highly reflective ohmic contact layer formed on the lower surface of the second conductive nitride semiconductor layer; and a metal substrate formed on the lower surface of the highly reflective ohmic contact layer. In accordance with the present invention, provided are effects such as good heat release, reduction of forward voltage, and improvement of electrostatic discharge effects. In addition, a broad light emitting area can be secured, thereby improving LED luminance.

### RELATED APPLICATIONS

The present application is based on, and claims priority from, Korean Application Number 2004-66619, filed Aug. 24, 2004, the disclosure of which is incorporated by reference herein in its entirety.

### BACKGROUND OF THE INVENTION

1. Field of the Invention

The present invention relates to a vertical nitride semiconductor light emitting diode, and more particularly to a vertical nitride semiconductor light emitting diode having improved luminance and reliability.

2. Description of the Related Art

Recently, a great deal of attention has been directed to nitride semiconductors using nitrides such as GaN, as a photoelectric material and a core material for electronic devices, since they have excellent physical and chemical properties. In particular, a nitride semiconductor light emitting diode produces green, blue color and UV light, and as a result of technological advancement, has a marked improvement in luminance thereof, therefore it is also applied to full color sign boards, illumination devices, and the like.

The nitride semiconductor light emitting diode is made of a semiconductor material having the formula of AlₓIn_{y}Ga_{(1-x-y)}N wherein x, y and the sum of x and y are independently between 0 and 1. Nitride semiconductor crystals are grown on a substrate for growing nitride single crystals, such as a sapphire substrate, considering the lattice matching therebetween. The sapphire substrate is electrically insulative and thus, a final nitride semiconductor light emitting diode has a structure having both p- and n-electrodes formed on the same surface.

Now, a conventional nitride semiconductor light emitting diode will be specifically described with reference to a structure of the conventional nitride semiconductor light emitting diode shown in FIG. 1.

FIG. 1 is a cross-sectional view showing a structure of the conventional nitride semiconductor light emitting diode. Referring to FIG. 1, the conventional nitride semiconductor light emitting diode has a structure having a light emitting structure that is made up of nitride single crystals consisting of a plurality of layers formed on a substrate 11. More specifically, the conventional nitride semiconductor light emitting diode is formed by growing an n-type nitride semiconductor layer 12, an active layer 13 and a p-type nitride semiconductor layer 14 laminated sequentially on the substrate 11, and forming electrodes 15, 16a and 16b on the n- and p-type nitride semiconductor layers 12 and 14, respectively, and produce light from the active layer 13 by recombination of holes and electrons injected from the semiconductor layers 12 and 14. At this time, the light generated from the active layer 13 is emitted to a transparent electrode layer 15 disposed on the p-type nitride semiconductor layer 14, or the substrate 11. The transparent electrode layer 15 is a light transmissive electrode made of a metal thin film or a transparent conductive film formed on almost the entire surface of the p-type nitride semiconductor layer 14 and is designed to form ohmic contact.

As described above, since the conventional nitride semiconductor light emitting diode 10 uses the sapphire substrate 11 which is an insulative material, there is no alternative but to form electrodes 15, 16a and 16b in a nearly horizontal direction. Therefore, it is inevitable that when applying voltage, current flow directed to the p-type electrode 16b through the active layer 13 from the n-type electrode 16a is narrowly formed along a horizontal direction. Due to such narrow current flow, the conventional nitride semiconductor light emitting diode suffers from increased forward voltage (Vf), thus reducing current efficiency, and poor electrostatic discharge effects.

Further, the conventional nitride semiconductor light emitting diode 10 may exhibit disadvantages such as high heat production due to increased current density, while poor heat release due to low thermal conductivity of the sapphire substrate 11, and thus heat increase causing occurrence of mechanical stress between the sapphire substrate 11 and a nitride semiconductor light emitting structure, resulting in instability of the light emitting diode.

Still further, in order to form the n-type electrode 16a in the conventional nitride semiconductor light emitting diode 10, since it is necessary to remove portions of the active layer 13 and p-type nitride semiconductor layer 14 at least larger than the area of the n-type electrode 16a to be formed, there are also problems such as reduction of light emitting area and thus deterioration of light emitting efficiency according to size of the light emitting diode versus luminance.

Therefore, there is a need for a new structure of a nitride semiconductor light emitting diode capable of improving luminance and reliability thereof by resolving the problems caused by the sapphire substrate necessary for growing single crystals of the nitride semiconductor materials.

### SUMMARY OF THE INVENTION

Therefore, the present invention has been made in view of the above problems, and it is an object of the present invention to provide a nitride semiconductor light emitting diode having a vertical structure in which electrodes are formed on both oppositely facing sides of the diode, by removing an insulative sapphire substrate having low thermal conductivity and attaching a metal substrate.

In accordance with the present invention, the above and other objects can be accomplished by the provision of a vertical nitride semiconductor light emitting diode comprising:
a first conductive nitride semiconductor layer including an upper surface having a first electrode formed thereon;
an active layer formed on a lower surface of the first conductive nitride semiconductor layer;
a second conductive nitride semiconductor layer formed on a lower surface of the active layer;
a highly reflective ohmic contact layer formed on the lower surface of the second conductive nitride semiconductor layer; and
a metal substrate formed on the lower surface of the highly reflective ohmic contact layer.

Preferably, in the vertical nitride semiconductor light emitting diode in accordance with the present invention, the metal substrate is made of metal materials having a thermal expansion coefficient of 4 to 7 ppm/K. As the representative examples of metal materials of the metal substrate may be made of As, Cr, Gd, Ge, Hf, Mo, Nd and Zr. The highly reflective ohmic contact layer may include at least one layer made of materials selected from the group consisting of Ag, Ni, Al, Rh, Pd, Ir, Ru, Mg, Zn, Pt, Au and any combination thereof.

In one embodiment of the present invention, the vertical nitride semiconductor light emitting diode may further comprise a conductive bonding layer formed between the highly reflective ohmic contact layer and metal substrate. The conductive bonding layer may be made of material selected from the group consisting of Au—Sn, Sn, In, Au—Ag and Pb—Sn may be used.

Meanwhile, in the vertical nitride semiconductor light emitting diode in accordance with the present invention, in order to further improve distribution of current density, preferably, the first conductive nitride semiconductor layer is formed of an n-type impurity doped nitride semiconductor layer and the second conductive nitride semiconductor layer is formed of a p-type impurity doped nitride semiconductor layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side cross-sectional view schematically showing a structure of a conventional nitride semiconductor light emitting diode;

FIG. 2 is a side cross-sectional view schematically showing a vertical nitride semiconductor light emitting diode in accordance with the preferred embodiment of the present invention;

FIG. 3a is an enlarged photograph showing contamination of a highly reflective ohmic contact layer caused by a Si substrate;

FIG. 3b is an enlarged photograph showing state of a highly reflective ohmic contact layer of a vertical nitride semiconductor light emitting diode using a metal substrate of the present invention;

FIGS. 4a through 4d are process cross-sectional views of respective steps illustrating a process for preparing a vertical nitride semiconductor light emitting diode in accordance with the present invention; and

FIGS. 5a through 5f are side cross-sectional views of respective steps illustrating a process for separating a sapphire substrate used in the preferred embodiment of the present invention.

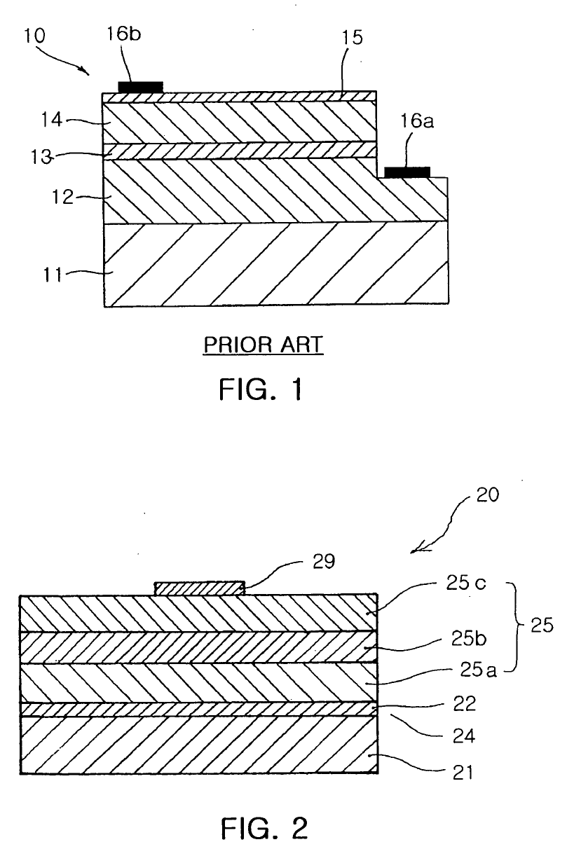

### DESCRIPTION OF THE PREFERRED EMBODIMENTS

The present invention will now be described in detail with reference to the annexed drawings.

FIG. 2 is a side cross-sectional view of a vertical nitride semiconductor light emitting diode 20 in accordance with the preferred embodiment of the present invention. As shown in FIG. 2, the vertical nitride semiconductor light emitting diode 20 in accordance with the present invention comprises a light emitting structure 25 including a p-type nitride semiconductor layer 25a, an active layer 25b and an n-type nitride semiconductor layer 25c, and a highly reflective ohmic contact layer 22 formed on the lower surface of the p-type nitride semiconductor layer 25a and a metal substrate 21 bonded to the highly reflective ohmic contact layer 22. In this structure, the vertical nitride semiconductor light emitting diode 20 may further comprise a conductive bonding layer (not shown) formed between the highly reflective ohmic contact layer 22 and metal substrate 21.

The light emitting structure 25 which is made up of single crystals of nitride semiconductor materials is grown on the sapphire substrate, but attaching the metal substrate 21 to a side opposite the sapphire substrate and removing the sapphire substrate thus realize a vertical structure like the nitride semiconductor light emitting diode 20 shown in FIG. 2.

The highly reflective ohmic contact layer 22 is a layer designed to suitably lower contact resistance with the p-type nitride semiconductor layer 25a having a relatively high energy band gap and at the same time, to improve effective luminance directed toward the upper surface of the diode, and may be made of highly reflective metals. The highly reflective ohmic contact layer 22 plays the same role, and may be made of the same materials and have the same structure, as the highly reflective ohmic contact layer provided in the light emitting diode used in a flip chip structure of light emitting devices. In order to satisfy contact resistance improvement and requirements of high reflectivity, the highly reflective ohmic contact layer 22 may be formed of at least one layer made of materials selected from the group consisting of Ag, Ni, Al, Rh, Pd, Ir, Ru, Mg, Zn, Pt, Au and any combination thereof and preferably has a reflectivity of more than 70%. More preferably, the highly reflective ohmic contact layer 22 may be formed of a bilayer structure including a first layer made of material selected from the group consisting of Ni, Pd, Ir, Pt and Zn, and a second layer made of material selected from the group consisting of Ag and Al and formed on the first layer. Most preferably, the highly reflective ohmic contact layer 22 may be formed of a trilayer structure including a first layer made of Ni, a second layer made of Ag and formed on the first layer and a third layer made of Pt and formed on the second layer.

Optionally, a conductive bonding layer may be formed between the highly reflective ohmic contact layer 22 and metal substrate 21. The conductive bonding layer is designed to further reinforce contact between the highly reflective ohmic contact layer 22 and metal substrate 21, and may be made of adhesive conductive materials. As examples of such materials, metal adhesive materials selected from the group consisting of Au—Sn, Sn, In, Au—Ag and Pb—Sn are preferably used. This conductive bonding layer is primarily used when materials to be contacted are non-metallic materials such as Si. Since the present invention uses the metal substrate 21, there is an advantage of providing relatively strong bonding without using the conductive bonding layer.

Upon considering thermal expansion coefficient differences between the metal substrate 21 and nitride semiconductor material, the metal substrate 21 is preferably made of metal materials having a thermal expansion coefficient of 4 to 7 ppm/K. In particular, the metal substrate 21 may be made of materials selected from the group consisting of As, Cr, Gd, Ge, Hf, Mo, Nd and Zr. Metal elements presented as materials for the metal substrate 21 have characteristics in that they are metal materials exhibiting a small difference in thermal expansion coefficient with that of nitride semiconductor materials, and in particular, GaN. If the metal substrate is made of materials exhibiting a large difference in thermal expansion coefficient with that of the nitride semiconductor materials, the sapphire substrate having the light emitting structure grown thereon may be broken due to thermal expansion coefficient differences therebetween.

Table 1 below shows thermal expansion coefficients of metal materials which can be used as the metal substrate of the present invention, and Si which may be used instead of the metal substrate.

TABLE 1

| | Thermal expansion |
|---|---|
| Materials | coefficient(ppm/K) |
| GaN | 5.59 |
| As | 5.6 |
| Cr | 6.5 |
| Gd | 6.4 |
| Ge | 5.75 |
| Hf | 6.0 |
| Mo | 5.1 |
| Nd | 6.7 |
| Zr | 5.9 |
| Si | 2.6 |

As can be seen from Table 1, GaN, a representative nitride semiconductor material, has a thermal expansion coefficient of 5.59 ppm/K. Therefore, materials constituting the metal substrate are preferably metal materials having a thermal expansion coefficient of 4 to 7 ppm/K. Representatively, As, Cr, Gd, Ge, Hf, Mo, Nd and Zr are all metal materials having a thermal expansion coefficient of 5 to 7 ppm/K and exhibit small differences in thermal expansion coefficient with that of GaN, a nitride semiconductor material. Conversely, Si has a relatively large thermal expansion coefficient as compared to materials presented as the materials for the metal substrate. Therefore, when using a Si substrate, in the course of a bonding process, the sapphire substrate having the light emitting structure grown thereon may be damaged due to stress resulting from the thermal expansion coefficient differences.

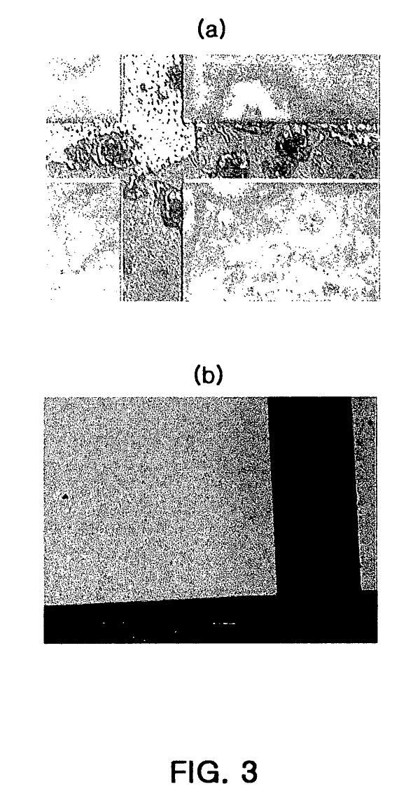

Further, in the case of the Si substrate, for bonding the light emitting structure to the substrate, it is imperative to form the conductive bonding layer. However, Si reacts with constituents of the conductive bonding layer to form compounds that in turn contaminate the highly reflective ohmic contact layer, thus causing problems associated with reflectivity. FIG. 3a is an enlarged photograph showing contamination of a highly reflective ohmic contact layer caused by the conductive bonding layer when using the Si substrate. This contamination of a highly reflective ohmic contact layer may cause significant problems such as luminance reduction of the light emitting diode.

In contrast, FIG. 3b is an enlarged photograph showing the state of a highly reflective ohmic contact layer when using a metal substrate of the present invention. This is a result for the metal substrate using, in particular, Mo, as the constituting material. It can be seen from FIG. 3b that the highly reflective ohmic contact layer was minimally contaminated and thus clean, unlike the state shown in FIG. 3a. Further, unlike when using the Si substrate, it is possible to eliminate use of an additional conductive bonding layer. Therefore, when using the metal substrate, it is possible to secure higher luminance through prevention of contamination of the reflective layer, as compared to when using the semiconductor substrate such as Si, and also to eliminate the need for the conductive bonding layer, thus resulting in process simplification and production cost reduction.

In addition, Si should be doped with impurities in order to obtain good conductivity. Furthermore, even though Si would have conductivity by impurity doping, it is required to provide an additional electrode made of metals on the lower surface of the substrate when using the Si substrate. In contrast, the metal substrate has sufficient conductivity by itself and thereby there is no need for an additional electrode. This contributes to process simplification and production cost reduction.

As described above, the vertical nitride semiconductor light emitting diode 20 in accordance with this embodiment has a structure in which the upper and lower parts thereof can be electrically conducted. Consequently, the vertical nitride semiconductor light emitting diode as shown in FIG. 2 is accomplished having the n-type electrode 29 formed on a portion of the upper surface of the n-type nitride semiconductor layer 25c, and using the metal substrate as the p-type electrode without addition of an electrode formation process.

The vertical nitride semiconductor light emitting diode 20 in accordance with this embodiment provides various advantages over conventional horizontal light emitting diodes. First, it is possible to realize good heat release effects due to use of the metal substrate 21 instead of the sapphire substrate, reduction of forward voltage (Vf) due to formation of current flow through a larger area than in the conventional horizontal light emitting diode and improvement of electrostatic discharge effects.

Further, from the standpoint of the process, a firm sapphire substrate is removed and thus the process of cutting into individual element units may be simplified. And also, in terms of LED luminance, unlike the conventional horizontal light emitting diodes, there is no need for a process of etching a portion of the active layer, and thus it is possible to obtain advantages such as securing a large light emitting area and thereby improving luminance.

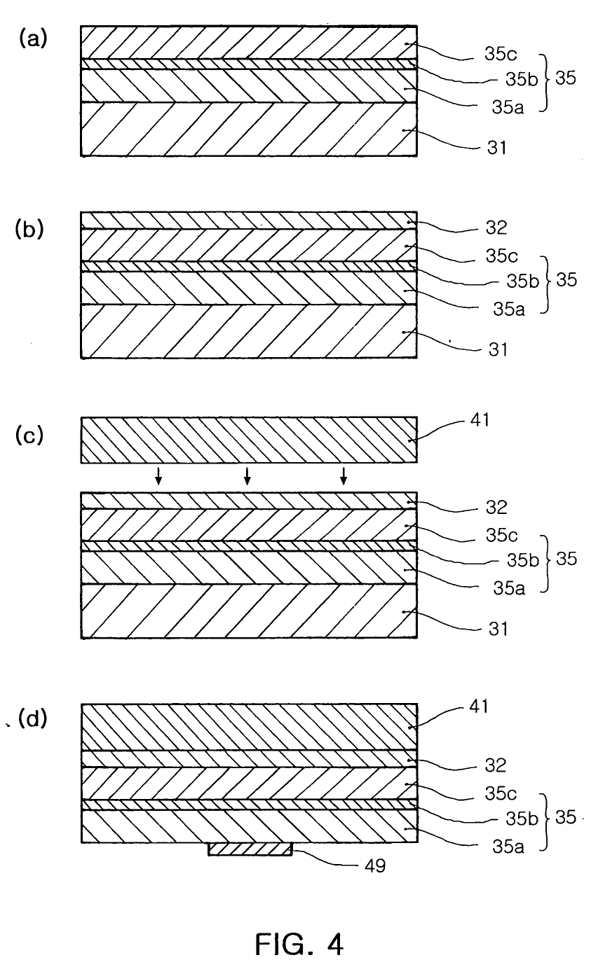

For better understanding of the structure of the vertical nitride semiconductor light emitting diode in accordance with the present invention, a process for preparing the same will be briefly described with reference to FIGS. 4a through 4d. For convenience of illustration, the process for preparing one vertical nitride semiconductor light emitting diode is exemplified in FIGS. 4a through 4d, even though the process is performed by production of a plurality of light emitting diodes using wafers.

As shown in FIG. 4a, the process for preparing a vertical nitride semiconductor light emitting diode in accordance with the present invention is initiated by the step of growing a light emitting structure 35 made up of single crystals of the nitride semiconductor materials, on a sapphire substrate 31. As previously described, the nitride semiconductor light emitting structure 35 may be grown using the sapphire substrate 31 as a growth substrate. In order to grow better quality crystals, the light emitting structure 35 may also be grown after forming a buffer layer (not shown) such as a GaN/AlN crystal layer on the sapphire substrate 31.

In addition, when it is desired to dispose the n-type vertical nitride semiconductor layer 35a on the upper part of the final LED, since the present upper/lower positions are reversed in the final structure, an n-type vertical nitride semiconductor layer 35a, an active layer 35b and a p-type vertical nitride semiconductor layer 35c are sequentially formed, as shown in FIG. 4a.

Next, as shown in FIG. 4b, in order to improve effective luminance of the light emitting diode, a highly reflective ohmic contact layer 32 is formed on the p-type nitride semiconductor layer 35c. The highly reflective ohmic contact layer 32 may be formed of at least one layer made of materials selected from the group consisting of Ag, Ni, Al, Rh, Pd, Ir, Ru, Mg, Zn, Pt, Au and any combination thereof. The highly reflective ohmic contact layer 32 forms ohmic contact with other single crystal structures, thus being able to smoothly conduct electric current in a vertical direction. The highly reflective ohmic contact layer 32 may be easily formed by those skilled in the art using conventional sputtering apparatuses.

Then, as shown in FIG. 4c, a metal substrate 41 is bonded on the highly reflective ohmic contact layer 32. In the process for preparing a vertical nitride semiconductor light emitting diode in accordance with the present invention, it is possible to effect bonding between the highly reflective ohmic contact layer 32 and metal subsrate 41 without using the conductive bonding layer, but the conductive bonding layer may be optionally used. In the case of forming and bonding the conductive bonding layer, the conductive bonding layer may be formed previously on either the highly reflective ohmic contact layer 32 or the lower surface of the metal substrate 41, or may be formed on both of them.

As shown in FIG. 4d, upon completing a bonding process of the metal substrate 41, the sapphire substrate (reference numeral 31 in FIG. 4c) is removed. The sapphire substrate may be removed by using any one of known substrate removal techniques such as laser melting, mechanical grinding and chemical etching. However, since the sapphire substrate has a very firm hexahedral aluminum oxide (Al₂O₃) crystal structure, use of mechanical grinding or chemical etching increases processing costs and time. Therefore, a separation method using thermal expansion coefficient differences between the sapphire substrate and the light emitting structure made of nitride semiconductor materials is largely employed. As a representative method, the separation using laser beams may be mentioned. After removing the sapphire substrate, formation of an n-type electrode 49 on the exposed surface of the n-type nitride semiconductor layer from which the sapphire substrate was finally removed accomplishes a vertical nitride semiconductor light emitting diode.

As described above, the vertical nitride semiconductor light emitting diode in accordance with the present invention is made in the form of a vertical structure and thereby reliability and luminance thereof can be remarkably improved.

Further, for convenient illustration of the present process, a process for individual element units was exemplified, but where a plurality of light emitting diodes are simultaneously produced using wafers as in the practical process, the firm sapphire substrate is previously removed which causes additional processes and costs in a process of cutting a plurality of light emitting diodes into individual units, and thereby the cutting process may be simplified.

In the above-mentioned process for preparing a vertical nitride semiconductor light emitting diode, there are many known processes of separating the sapphire substrate, as described before, but they present various problems in practical application. In particular, even use of the separation technique using laser beams, which may be presented as the preferred process, may have problems such as damage to crystal faces of the nitride semiconductor in the course of laser beam irradiation due to the thermal expansion coefficient difference and lattice mismatching between the sapphire substrate and single crystal nitride semiconductor light emitting structure.

Generally, in order to separate the sapphire substrate, when irradiating laser beams on the lower part of the sapphire substrate, residual stress occurs due to the thermal expansion coefficient difference and lattice mismatching between the sapphire substrate and nitride semiconductor single crystal layer. That is, the thermal expansion coefficient of sapphire is about 7.5×10⁻⁶ ppm/K, while that of nitride semiconductor single crystal (in the case of GaN) is about 5.59×10⁻⁶ ppm/K, and thus there is lattice mismatching of about 16% therebetween. Similarly, also in forming a GaN/AlN buffer layer, there are several % of lattice mismatching, and thereby large compressive stress and tensile stress occur on surfaces of the sapphire substrate and nitride semiconductor single crystal layer, respectively, when the surfaces are heated by laser beams. In particular, since laser beams are locally and repeatedly irradiated on the sapphire substrate several times due to narrow irradiation area of the laser beam (maximum of 10 mm×10 mm), the problem associated with occurrence of stress becomes more serious and thus the surface of the nitride semiconductor single crystal layer may be significantly damaged. After all, such damaged single crystal faces greatly degrade electrical characteristics of the final GaN light emitting diode.

In order to overcome these problems, in the process for preparing a vertical nitride semiconductor light emitting diode in accordance with the present invention, it is preferred to use a method of previously cutting the nitride semiconductor single crystal layer into individual element units on the sapphire substrate so as to minimize effects of stress on the surface of the nitride semiconductor single crystal layer when separating the sapphire substrate. Now, a process for preparing a preferred vertical nitride semiconductor light emitting diode will be described involving previously cutting the nitride semiconductor single crystal layer into individual element units on the sapphire substrate so as to minimize effects of stress on the surface of the nitride semiconductor single crystal layer when separating the sapphire substrate.

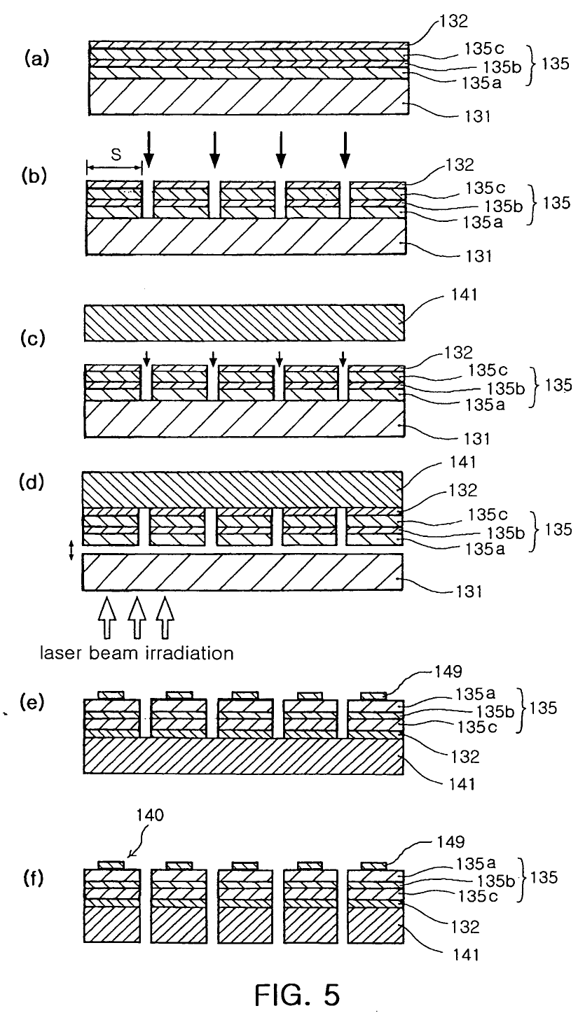

FIGS. 5a through 5f are side cross-sectional views of respective steps illustrating a process for separating a sapphire substrate used in the preferred embodiment of the present invention.

Referring to FIG. 5a, a light emitting structure 135 made of the nitride semiconductor single crystal layers is formed on a sapphire substrate 131, and a highly reflective ohmic contact layer 132 is formed on the light emitting structure 135. The nitride semiconductor single crystal layers constituting the light emitting structure 135 include an n-type nitride semiconductor layer 135a, an active layer 135b and a p-type nitride semiconductor layer 135c.

Next, as shown in FIG. 5b, the highly reflective ohmic contact layer 132 and nitride semiconductor light emitting structure 135 are cut to a predetermined size (S). Like this embodiment, without performing an additional cutting process for the emitting structure part and in order to minimize occurrence of stress due to laser beam irradiation by miniaturizing the size (S) of the light emitting structures as much as possible, the predetermined size preferably corresponds to that of the final light emitting diode. However, there is no particular limitation to the size of the light emitting structures, and even when cutting the light emitting structure into a size almost equal to or smaller than the irradiation area of the laser beam, stress occurring on the nitride semiconductor single crystal faces can be sufficiently reduced.

Next, as shown in FIG. 5c, a metal substrate 141 is bonded to the upper surface of the cut highly reflective ohmic contact layer 132. At this time, although a conductive bonding layer (not shown) may be formed on the surface of the metal substrate 141 which contacts the ohmic contact layer 132, since the present invention, as described above, uses a substrate made of metal materials, thus accomplishing relatively strong bonding without using the conductive bonding layer, it is preferred to eliminate use of the conductive bonding layer. In this manner, by bonding the metal substrate 141 on the cut light emitting structures 135 and the upper surface of the highly reflective ohmic contact layer 132, the respective cut light emitting structures 135 can be stably arranged even when the sapphire substrate 131 is separated later and therefore, subsequent processes such as contact formation can be easily performed in an arranged state by masking and the like.

Next, as shown in FIG. 5d, the sapphire substrate is separated from respective cut light emitting structures 135 using instantaneous stress produced by irradiating the laser beam to the lower part of the sapphire substrate 131. At this time, in terms of stress occurring at interfaces of the light emitting structures 135, occurrence of residual stress can be more reduced, proportional to the decreased area of the light emitting structures, as compared to when irradiating the laser beam to a wafer having a large diameter.

Further, the irradiation area of the laser beam in this process is generally smaller than area of the wafer, the separation process of the sapphire substrate is performed by repeatedly irradiating the laser beam several times. Therefore, in order that, when irradiating a single laser beam, the irradiated part can be separated, the size to be cut in the cutting process of the light emitting structure in FIG. 5b preferably corresponds to at least a laser beam irradiation area.

Next, as shown in FIG. 5e, formation of the n-type electrode 149 is performed on the upper surface of the n-type nitride semiconductor layer 135a of the resulting materials. FIG. 5e shows the states of the resulting materials of FIG. 5d in which the upper and lower parts thereof were reversed. The n-type electrode 149 formed on the upper surface of the n-type nitride semiconductor layer 135a may be selectively formed on only a portion thereof (generally, middle part of the upper surface) by masking. As described above, since the present invention uses the metal substrate 141, additional formation of the p-type electrode can be eliminated and the metal substrate 141 can be employed as the p-type electrode.

Finally, as shown in FIG. 5f, the final vertical nitride semiconductor light emitting diode 140 can be obtained by cutting the resulting materials from the FIG. 5e process into sizes of individual light emitting diodes. Where previously cutting the light emitting structure 135 into sizes of individual light emitting diodes in the process of FIG. 5b, this process is done with the cutting process of the metal substrate 141 only. In contrast, where cutting the light emitting structure 135 into a size corresponding to the area irradiated by the laser beam, the cutting process of the light emitting structure 135 may be simultaneously performed.

As apparent from the above description, in accordance with the vertical nitride semiconductor light emitting diode of the present invention, provided are effects such as good heat release due to removal of the sapphire substrate and use of the metal substrate, reduction of forward voltage due to formation of current flow through a broader area as compared to a conventional horizontal light emitting diode, and improvement of electrostatic discharge effects. And also, a firm sapphire substrate is removed and thereby a process of cutting a light emitting structure into individual element units can be simplified.

Further, in terms of LED luminance, unlike the conventional horizontal light emitting diode, there is no need for a process of etching a portion of the active layer, and thus it is possible to obtain advantages such as securing a larger light emitting area and thereby improving luminance. In addition, use of the metal substrate makes it possible to eliminate a process for forming an additional bonding layer when bonding the metal substrate to the light emitting structure. And also, in order to conduct electricity to upper/lower parts of the vertical nitride semiconductor light emitting diode, formation of an electrode on one side thereof only and use of the metal substrate itself as the electrode make it possible to eliminate a additional process for forming the electrode, and thereby effects such as simplification of a process for preparing a vertical nitride semiconductor light emitting diode and reduction of production costs can be accomplished.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A vertical nitride semiconductor light emitting diode comprising:
a first conductive nitride semiconductor layer including an upper surface having a first electrode formed thereon;
an active layer formed on a lower surface of the first conductive nitride semiconductor layer;
a second conductive nitride semiconductor layer formed on a lower surface of the active layer;
a highly reflective ohmic contact layer formed on the lower surface of the second conductive nitride semiconductor layer; and
a metal substrate formed on the lower surface of the highly reflective ohmic contact layer.

2. The vertical nitride semiconductor light emitting diode as set forth in claim 1, wherein the metal substrate is made of metal material having a thermal expansion coefficient of 4 to 7 ppm/K.

3. The vertical nitride semiconductor light emitting diode as set forth in claim 1, wherein the metal substrate is made of material selected from the group consisting of As, Cr, Gd, Ge, Hf, Mo, Nd and Zr.

4. The vertical nitride semiconductor light emitting diode as set forth in claim 1, wherein the highly reflective ohmic contact layer includes at least one layer made of material selected from the group consisting of Ag, Ni, Al, Rh, Pd, Ir, Ru, Mg, Zn, Pt, Au and any combination thereof.

5. The vertical nitride semiconductor light emitting diode as set forth in claim 1, further comprising:
a conductive bonding layer formed between the highly reflective ohmic contact layer and metal substrate.

6. The vertical nitride semiconductor light emitting diode as set forth in claim 5, wherein the conductive bonding layer is made of material selected from the group consisting of Au—Sn, Sn, In, Au—Ag and Pb—Sn.

7. The vertical nitride semiconductor light emitting diode as set forth in claim 1, wherein the first conductive nitride semiconductor layer is an n-type impurity doped nitride semiconductor layer, and the second conductive nitride semiconductor layer is a p-type impurity doped nitride semiconductor layer.
